(19) United States
(12) Patent Application Publication
(10) Pub. No.: US 2026/0268960 A1
(43) Pub. Date: Sep. 10, 2026

(54) SEMICONDUCTOR DEVICE CAPABLE OF SWITCHING OPERATION VOLTAGE

(71) Applicant: Micron Technology, Inc., Boise, ID (US)

(72) Inventors: Ikuma Miwa, Hino-shi (JP); Yoshifumi Mochida, Kanagawa (JO)

(73) Assignee: Micron Technology, Inc., Boise, ID (US)

(21) Appl. No.: 19/547,510

(22) Filed: Feb. 23, 2026

Related U.S. Application Data
(60) Provisional application No. 63/766,853, filed on Mar. 4, 2025.

(51) Int. Cl. G11C 11/4074; G05F 3/24; G11C 11/408

(52) U.S. Cl. CPC G11C 11/4074; G05F 3/24; G11C 11/4087

(57) ABSTRACT

An example apparatus includes a first external power supply line supplied with a first external power voltage, a second external power supply line supplied with a second external power voltage different from the first external power voltage, a first internal power supply line, an internal voltage generator coupled in parallel to the first external power supply line and the second external power supply line and configured to supply a voltage to the first internal power supply line based on a selected one of the first external power voltage and the second external power voltage, and a pull-down circuit coupled to the first internal power supply line and configured to lower the voltage of the internal power supply line when the voltage of the internal power supply line.

### CROSS-REFERENCE TO RELATED APPLICATIONS

This application claims the filing benefit of U.S. Provisional Application No. 63/766,853, filed Mar. 4, 2025. This application is incorporated by reference herein in its entirety and for all purposes.

### BACKGROUND

There is a case where a semiconductor device such as a DRAM is configured to be able to switch an operation voltage of some of internal circuits thereof according to required operation speed and consumption current. Such a semiconductor device includes a power switch for switching the operation voltage. When the operation voltage is switched due to a change in the operation mode, it is desirable that the operation voltage reaches a predetermined voltage level quickly.

### BRIEF DESCRIPTION OF THE DRAWINGS

FIG. 1 is a block diagram showing a configuration of a semiconductor device according to the present disclosure;

FIG. 2 is a circuit diagram showing a configuration of main parts of an internal voltage generator;

FIG. 3 is a schematic diagram showing a relation among external power potentials and a regulator potential;

FIG. 4A to FIG. 4D are timing charts for explaining operations of switching the level of an internal power potential; and

FIG. 5 is a timing chart for explaining changes of the internal power potential at the time of turning power on.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

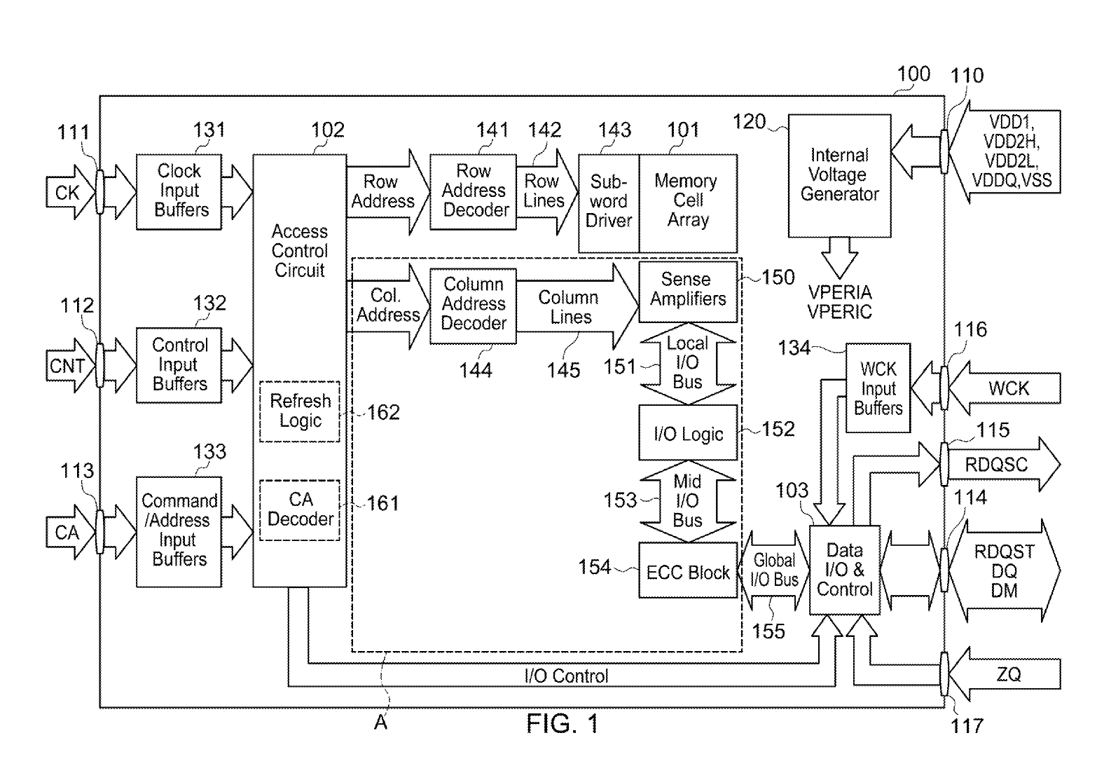

FIG. 1 is a block diagram showing a configuration of a semiconductor device 100 according to the present disclosure. The semiconductor device 100 shown in FIG. 1 is a DRAM, for example, and includes a memory cell array 101, an access control circuit 102 that performs an access to the memory cell array 101, an I/O control circuit 103 that performs inputting and outputting of data to/from the memory cell array 101, and a plurality of external terminals. The plurality of external terminals include a power supply terminal 110, a clock terminal 111, a control terminal 112, a command address terminal 113, a data I/O terminal 114, a strobe terminal 115, a write clock terminal 116, a calibration terminal 117, and the like. A plurality of external power potentials are supplied from outside to the power supply terminal 110. The plurality of external power potentials include VDD1, VDD2H, VDD2L, VDDQ, and VSS. These external power potentials are supplied to an internal voltage generator 120. The internal voltage generator 120 generates various internal power potentials based on at least the external power potentials VDD2H, VDD2L, and VSS. The internal power potentials generated by the internal voltage generator 120 include at least internal power potentials VPERIA and VPERIC.

A clock signal CK input from outside via the clock terminal 111 is supplied to the access control circuit 102 via clock input buffers 131. A control signal CNT input from outside via the control terminal 112 is supplied to the access control circuit 102 via control input buffers 132. A command address signal CA input from outside via the command address terminal 113 is supplied to the access control circuit 102 via command/address input buffers 133. The access control circuit 102 performs an access to the memory cell array 101 based on the command address signal CA and the control signal CNT. The access control circuit 102 is operated in synchronization with the clock signal CK. The control signal CNT may include a chip selection signal and a reset signal. The access control circuit 102 also controls the I/O control circuit 103.

When a command included in the command address signal CA indicates a read operation, the access control circuit 102 performs a read access to memory cells included in the memory cell array 101 based on an address included in the command address signal CA. Read data DQ read from the accessed memory cells is output to outside from the data I/O terminal 114 via the I/O control circuit 103. When the command included in the command address signal CA indicates a write operation, write data DQ input to the data I/O terminal 114 is transferred to the memory cell array 101 via the I/O control circuit 103. The write data DQ transferred to the memory cell array 101 is written in memory cells included in the memory cell array 101 based on the address included in the command address signal CA.

The access control circuit 102 includes a command address decoder 161 and a refresh logic 162. The command address decoder 161 generates a row address and a column address by decoding the command address signal CA. The row address generated by the command address decoder 161 is decoded by a row address decoder 141. The decoded row address is supplied to a sub-word driver 143 via row lines 142. The sub-word driver 143 performs a row access (selection of sub-word lines) to the memory cell array 101. In a refresh operation, a row address is generated by the refresh logic 162. The column address generated by the command address decoder 161 is decoded by a column address decoder 144. The decoded column address is supplied to sense amplifiers 150 via column lines 145. The sense amplifiers 150 perform a column access (selection of bit lines) to the memory cell array 101.

The sense amplifiers 150 are connected to an I/O logic 152 via a local I/O bus 151. The I/O logic 152 executes parallel-serial conversion of the read data DQ, serial-parallel conversion of the write data DQ, timing control of the read data DQ and the write data DQ, and the like. The I/O logic 152 is connected to an ECC block 154 via a middle I/O bus 153. The ECC block 154 performs generation of an error correction code, error correction on the write data DQ using the error correction code, and the like. The ECC block 154 is connected to the I/O control circuit 103 via a global I/O bus 155. In a read operation, the I/O control circuit 103 performs outputting of the read data DQ to the data I/O terminal 114, outputting of strobe signals RDQST and RDSQC to the data I/O terminal 114 and the strobe terminal 115, and the like. In a write operation, the I/O control circuit 103 performs inputting of the write data DQ and a data mask signal DM from the data I/O terminal 114, inputting of a write clock signal WCK from the write clock terminal 116 via a WCK input buffer 134, and the like. Further, in a calibration operation, a resistance value ZQ of an external resistance connected to the calibration terminal 117 is referred to.

Each of the circuits constituting the semiconductor device 100 is supplied with an internal power potential corresponding thereto. For example, the internal power potential VPERIA is supplied to the column address decoder 144, the column lines 145, the sense amplifiers 150, the local I/O bus 151, the I/O logic 152, the middle I/O bus 153, and the ECC block 154 surrounded by reference sign A. The internal power potential VPERIC is supplied to the command address decoder 161, the refresh logic 162, the global I/O bus 155, and the I/O control circuit 103.

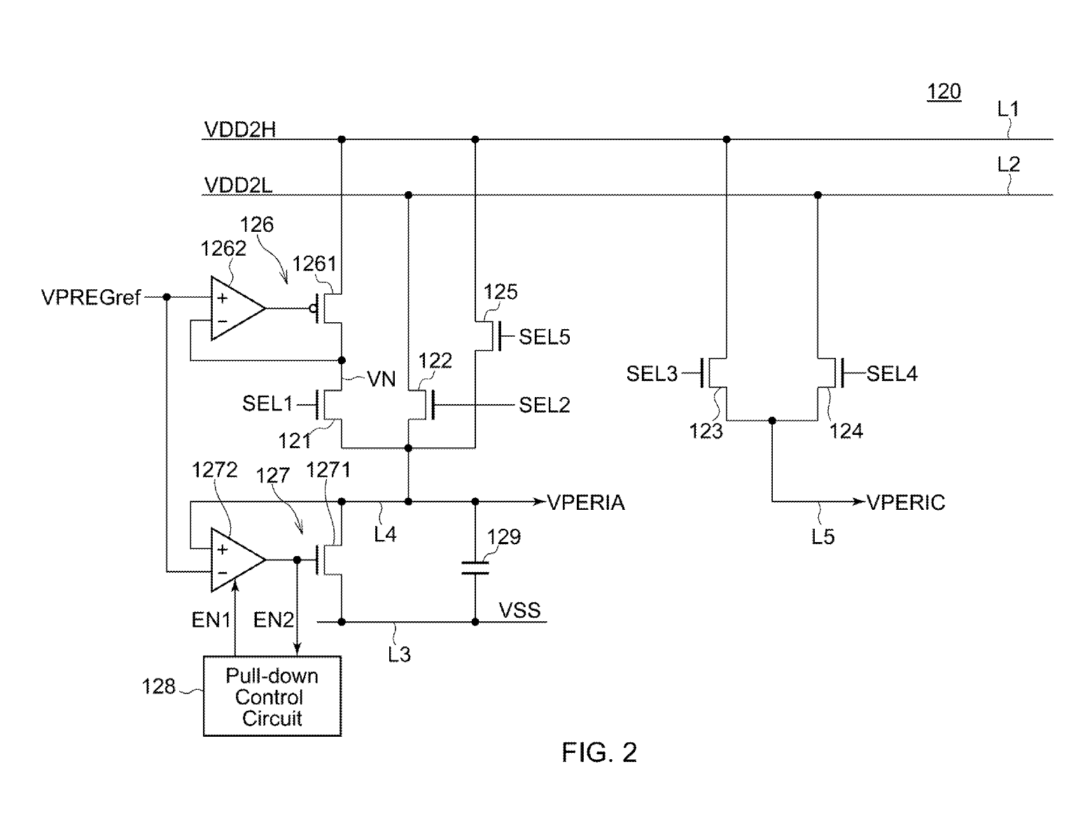

FIG. 2 is a circuit diagram showing a configuration of main parts of the internal voltage generator 120. As shown in FIG. 2, the internal voltage generator 120 includes power switches 121 to 125 each formed of an N-channel MOS transistor, a pull-up circuit 126, and a pull-down circuit 127. The pull-up circuit 126 is constituted of a pull-up transistor 1261 formed of a P-channel MOS transistor and a comparator 1262 that controls the pull-up transistor 1261. The pull-down circuit 127 is constituted of a pull-down transistor 1271 formed of an N-channel MOS transistor and a comparator 1272 that controls the pull-down transistor 1271. The comparator 1272 is operated under control of a pull-down control circuit 128.

The pull-up transistor 1261 and the power switch 121 are connected in series in this order between a power supply line L1 supplied with the external power potential VDD2H and a power supply line L4 suppling the internal power potential VPERIA. The power switch 122 is connected between a power supply line L2 supplied with the external power potential VDD2L and the power supply line L4 suppling the internal power potential VPERIA. The power switch 123 is connected between the power supply line L1 supplied with the external power potential VDD2H and a power supply line L5 suppling the internal power potential VPERIC. The power switch 124 is connected between the power supply line L2 supplied with the external power potential VDD2L and the power supply line L5 supplying the internal power potential VPERIC. The power switch 125 is connected between the power supply line L1 supplied with the external power potential VDD2H and the power supply line L4 supplying the internal power potential VPERIA.

A reference potential VPREGref is supplied to one of input nodes of the comparator 1262 and one of input nodes of the comparator 1272. The reference potential VPREGref is used as a reference potential when the level of the internal power potential VPERIA is set to be a regulator potential VPREG. The reference potential VPREGref may be equal to the regulator potential VPREG. When the comparator 1262 or the comparator 1272 has an offset, the reference potential VPREGref and the regulator potential VPREG are different from each other by the amount of the offset. The other input node of the comparator 1262 is connected to an internal power node VN, which is a coupling point between the pull-up transistor 1261 and the power switch 121. The internal power node VN is a common drain of the pull-up transistor 1261 and the power switch 121. An output node of the comparator 1262 is connected to a gate electrode of the pull-up transistor 1261. Accordingly, the regulator potential VPREG depending on the level of the reference potential VPREGref appears at the internal power node VN.

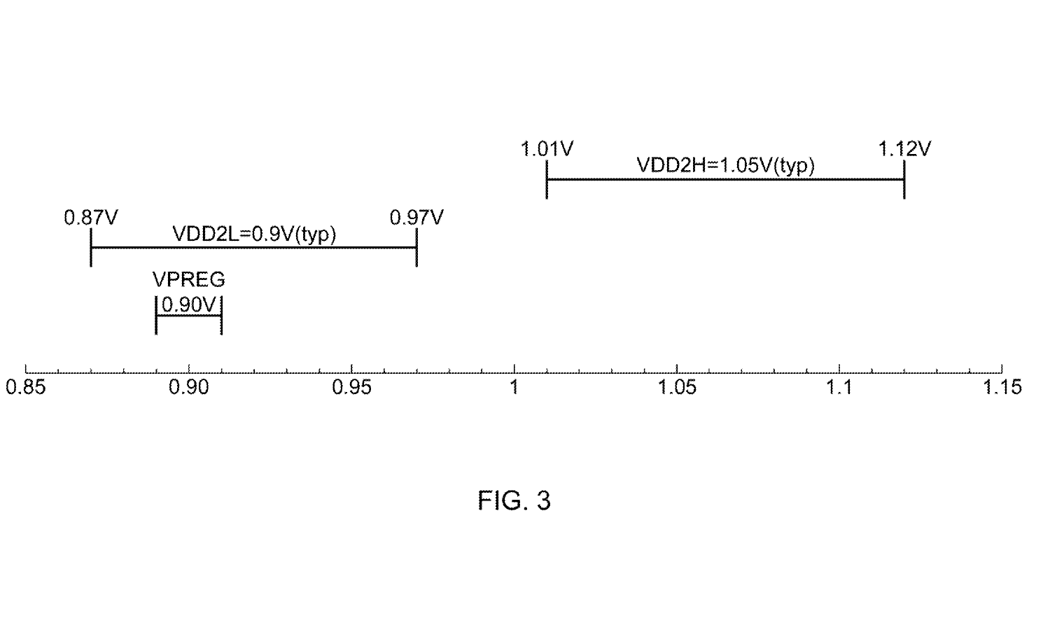

FIG. 3 is a schematic diagram showing a relation among the external power potential VDD2H, the external power potential VDD2L, and the regulator potential VPREG. In the example shown in FIG. 3, the typical value of the external power potential VDD2H is 1.05V and the typical value of the external power potential VDD2L is 0.9V. That is, the external power potential VDD2H is higher than the external power potential VDD2L. Note that the level of each of the external power potential VDD2H and the external power potential VDD2L has an acceptable range. The lower limit of the external power potential VDD2H is 1.01V and the upper limit thereof is1.12V. The lower limit of the external power potential VDD2L is 0.87V and the upper limit thereof is 0.97V. Meanwhile, the regulator potential VPREG is 0.90V and is a potential within the acceptable range of the external power potential VDD2L. The level of the regulator potential VPREG may have a tolerance of about ±0.01V. As shown in FIG. 3, the high-low relation between the external power potential VDD2L and the regulator potential VPREG is not fixed. That is, the regulator potential VPREG is higher than the external power potential VDD2L when the level of the external power potential VDD2L is close to its lower limit, and the regulator potential VPREG is lower than the external power potential VDD2L when the level of the external power potential VDD2L is close to its upper limit.

Selection signals SEL1 to SEL5 are supplied to corresponding gate electrodes of transistors constituting the power switches 121 to 125, respectively. The selection signals SEL1, SEL2, and SEL5 are activated independently of each other. The selection signals SEL3 and SEL4 are activated independently of each other. The selection signals SEL1 to SEL5 are generated by the access control circuit 102. When the selection signal SEL1 is activated, the power switch 121 is turned on, so that the level of the internal power potential VPERIA supplied to the power supply line L4 matches the regulator potential VPREG. When the selection signal SEL2 is activated, the power switch 122 is turned on, so that the level of the internal power potential VPERIA supplied to the power supply line L4 matches the external power potential VDD2L. When the selection signal SEL5 is activated, the power switch 125 is turned on, so that the level of the internal power potential VPERIA supplied to the power supply line L4 matches the external power potential VDD2H. When the selection signal SEL3 is activated, the power switch 123 is turned on, so that the level of the internal power potential VPERIC supplied to the power supply line L5 matches the external power potential VDD2H. When the selection signal SEL4 is activated, the power switch 124 is turned on, so that the level of the internal power potential VPERIC supplied to the power supply line L5 matches the external power potential VDD2L.

The other input node of the comparator 1272 is connected to the power supply line L4. An output node of the comparator 1272 is connected to a gate electrode of the pull-down transistor 1271. The pull-down transistor 1271 is connected between the power supply line L4 and a power supply line L3 supplied with the external power potential VSS. The external power potential VSS is 0V. The comparator 1272 is activated responsive to an enable signal EN1 supplied from the pull-down control circuit 128. When the comparator 1272 is activated, the level of the internal power potential VPERIA appearing at the power supply line L4 and the level of the reference potential VPREGref are compared to each other. When the internal power potential VPERIA is higher than the reference potential VPREGref, an enable signal EN2 is activated to be a high level. The enable signal EN2 is supplied to the gate electrode of the pull-down transistor 1271 and is fed back to the pull-down control circuit 128. When the enable signal EN2 is activated to be a high level, the pull-down transistor 1271 is turned on, so that the level of the internal power potential VPERIA appearing at the power supply line L4 is lowered.

An operation of switching the level of the internal power potential VPERIA is described next. Switching of the level of the internal power potential VPERIA is performed by issuing a mode register set command (MRS) from outside via the command address terminal 113.

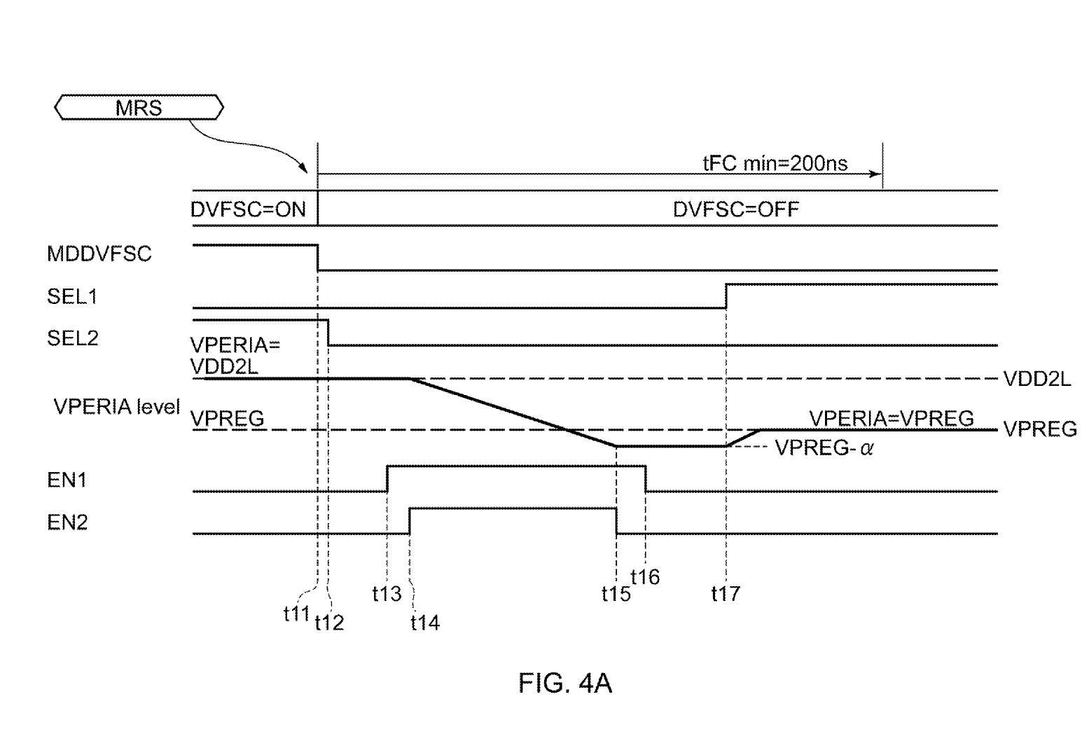

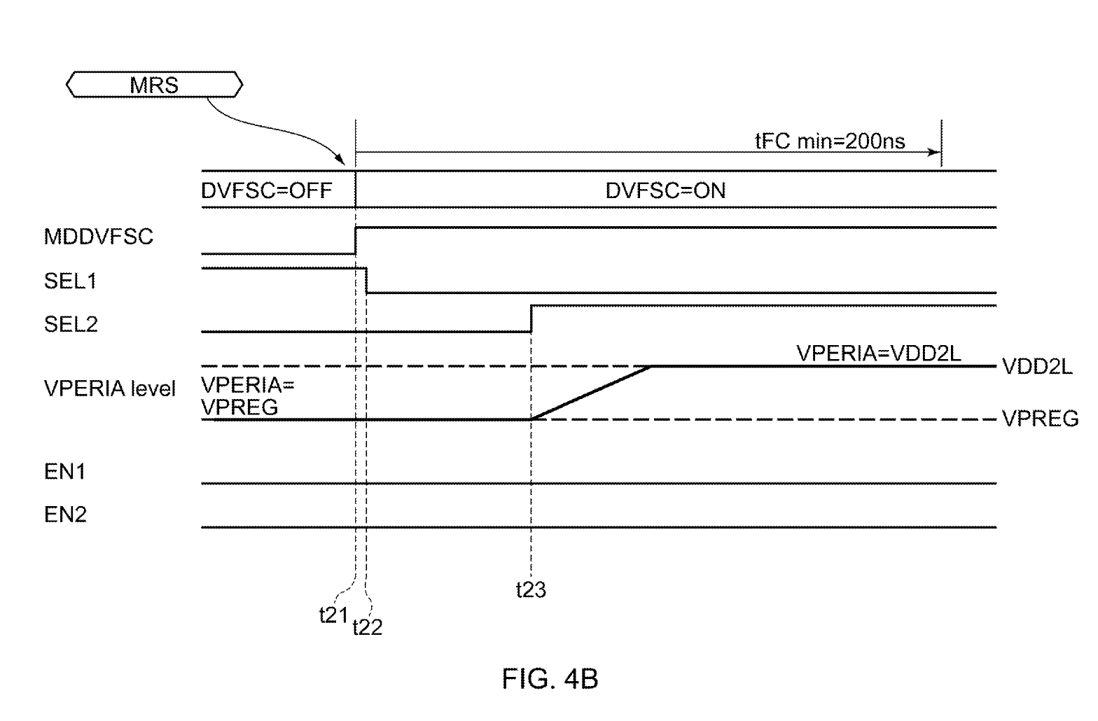

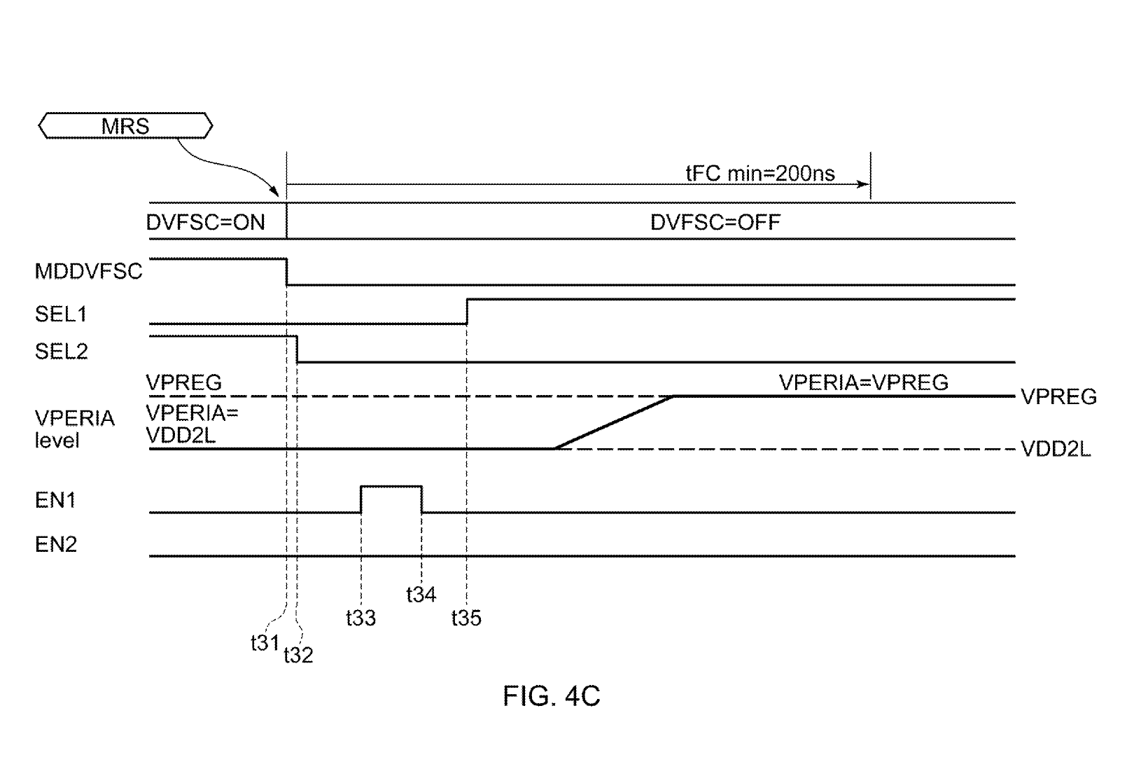

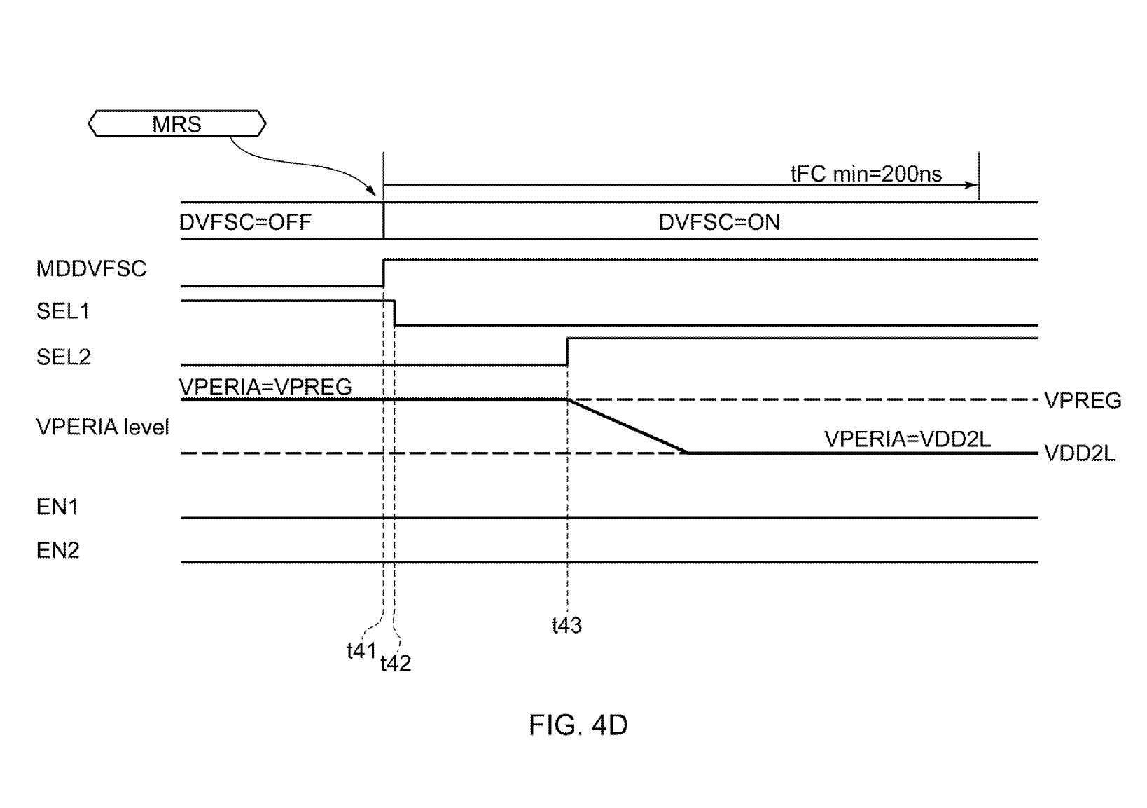

FIG. 4A is a timing chart for explaining an operation of switching the level of the internal power potential VPERIA from the external power potential VDD2L to the regulator potential VPREG when the regulator potential VPREG is lower than the external power potential VDD2L. First, when switching of the level of the internal power potential VPERIA is instructed with the mode register set command MRS, an internal signal MDDVFSC is changed from a high level to a low level at a time t11. The internal signal MDDVFSC is a signal specifying the level of the internal power potential VPERIA. The external power potential VDD2L is specified as the level of the internal power potential VPERIA (DVFSC=ON) when the internal signal MDDVFSC is at a high level, and the regulator potential VPREG is specified as the level of the internal power potential VPERIA (DVFSC=OFF) when the internal signal MDDVFSC is at a low level. Since the internal signal MDDVFSC is at a high level before the time t11, the selection signal SEL1 is at a low level and the selection signal SEL2 is at a high level. That is, the power switch 121 is off and the power switch 122 is on.

When the internal signal MDDVFSC is changed to a low level, the selection signal SEL2 is changed to a low level in response thereto at a time t12. Accordingly, both the power switches 121 and 122 enter an OFF state and thus power is not supplied to the power supply line L4. However, since a compensation capacitance 129 for stabilizing the internal power potential VPERIA is connected to the power supply line L4, the level of the power supply line L4 is kept substantially at the external power potential VDD2L. Further, the enable signal EN1 is activated at a time t13 in response to the change of the internal signal MDDVFSC to a low level. Accordingly, the comparator 1272 included in the pull-down circuit 127 is activated, and the level of the internal power potential VPERIA and the level of the reference potential VPREGref are compared to each other. In the example shown in FIG. 4A, the internal power potential VPERIA is higher than the reference potential VPREGref, so that the enable signal EN2 as the output from the comparator 1272 enters a high level at a time t14.

When the enable signal EN2 enters a high level, the pull-down transistor 1271 is turned on and the power supply line L4 is discharged. Accordingly, the level of the internal power potential VPERIA is gradually lowered. Thereafter, at a time t15, when the level of the internal power potential VPERIA is lowered to the regulator potential VPREG or around that level, the enable signal EN2 returns to a low level. When the enable signal EN2 returns to a low level, the pull-down control circuit 128 causes the enable signal EN1 to return to a low level at a time t16. In the example shown in FIG. 4A, the comparator 1272 has an offset and the enable signal EN2 is changed to a low level at a timing where the level of the internal power potential VPERIA reaches a value of the regulator potential VPREG-α. Accordingly, the level of the internal power potential VPERIA at the time t15 is slightly lower than the regulator potential VPREG.

Thereafter, at a time t17, the selection signal SEL1 is changed to a high level. Accordingly, the power switch 121 is turned on, so that the level of the internal power potential VPERIA supplied to the power supply line L4 becomes the regulator potential VPREG. Here, a minimal time tFC that is a time from a change of the internal signal MDDVFSC to switching of the level of the internal power potential VPERIA is specified to be, for example, 200ns by specifications. In the example shown in FIG. 4A, at a time point where the minimal time tFC has passed, the level of the internal power potential VPERIA has correctly reached the regulator potential VPREG.

The power switches 121 and 122 are both off during a period from the time t12 to the time t17. Therefore, if the pull-down circuit 127 is not provided, the level of the internal power potential VPERIA is inevitably kept around the external power potential VDD2L, and even at a time point where the minimal time tFC has passed, the level of the internal power potential VPERIA is inevitably higher than the regulator potential VPREG. In contrast thereto, since the internal voltage generator 120 according to the present embodiment includes the pull-down circuit 127, the level of the internal power potential VPERIA can be caused to reach the regulator potential VPREG within the minimal time tFC.

FIG. 4B is a timing chart for explaining an operation of switching the level of the internal power potential VPERIA from the regulator potential VPREG to the external power potential VDD2L when the regulator potential VPREG is lower than the external power potential VDD2L. First, when switching of the level of the internal power potential VPERIA is instructed with the mode register set command MRS, the internal signal MDDVFSC is changed from a low level to a high level at a time t21. Since the internal signal MDDVFSC is at a low level before the time t21, the selection signal SEL1 is at a high level and the selection signal SEL2 is at a low level. That is, it is a state where the power switch 121 is on and the power switch 122 is off. Next, the selection signal SEL1 is changed to a low level at a time t22. Accordingly, the power switches 121 and 122 are both turned off. Thereafter, the selection signal SEL2 is changed to a high level at a time t23. Accordingly, the power switch 122 is turned on, so that the level of the internal power potential VPERIA supplied to the power supply line L4 becomes the external power potential VDD2L. In a case where the internal signal MDDVFSC is changed from a low level to a high level, the enable signal EN1 is not activated.

FIG. 4C is a timing chart for explaining an operation of switching the level of the internal power potential VPERIA from the external power potential VDD2L to the regulator potential VPREG when the regulator potential VPREG is higher than the external power potential VDD2L. First, when switching of the level of the internal power potential VPERIA is instructed with the mode register set command MRS, the internal signal MDDVFSC is changed from a high level to a low level at a time t31. Since the internal signal MDDVFSC is at a high level before the time t31, the selection signal SEL1 is at a low level and the selection signal SEL2 is at a high level. That is, it is a state where the power switch 121 is off and the power switch 122 is on. Next, the selection signal SEL2 is changed to a low level at a time t32. Accordingly, the power switches 121 and 122 are both turned off.

When the internal signal MDDVFSC is changed to a low level, the enable signal EN1 is activated in response thereto at a time t33. Accordingly, the comparator 1272 included in the pull-down circuit 127 is activated and the level of the internal power potential VPERIA and the level of the reference potential VPREGref are compared to each other. Since the internal power potential VPERIA is lower than the reference potential VPREGref in the example shown in FIG. 4C, the enable signal EN2 as the output from the comparator 1272 is kept at a low level. As a result, time-out is detected by the pull-down control circuit 128 and the enable signal EN1 returns to a deactivated state at a time t34. Thereafter, the selection signal SEL1 is changed to a high level at a time t35. Accordingly, the power switch 121 is turned on, so that the level of the internal power potential VPERIA supplied to the power supply line L4 becomes the regulator potential VPREG.

FIG. 4D is a timing chart for explaining an operation of switching the level of the internal power potential VPERIA from the regulator potential VPREG to the external power potential VDD2L when the regulator potential VPREG is higher than the external power potential VDD2L. First, when switching of the level of the internal power potential VPERIA is instructed with the mode register set command MRS, the internal signal MDDVFSC is changed from a low level to a high level at a time t41. Since the internal signal MDDVFSC is at a low level before the time t41, the selection signal SEL1 is at a high level and the selection signal SEL2 is at a low level. That is, it is a state where the power switch 121 is on and the power switch 122 is off. Next, the selection signal SEL1 is changed to a low level at a time t42. Accordingly, the power switches 121 and 122 are both turned off. Thereafter, the selection signal SEL2 is changed to a high level at a time t43. Accordingly, the power switch 122 is turned on, so that the level of the internal power potential VPERIA supplied to the power supply line L4 becomes the external power potential VDD2L.

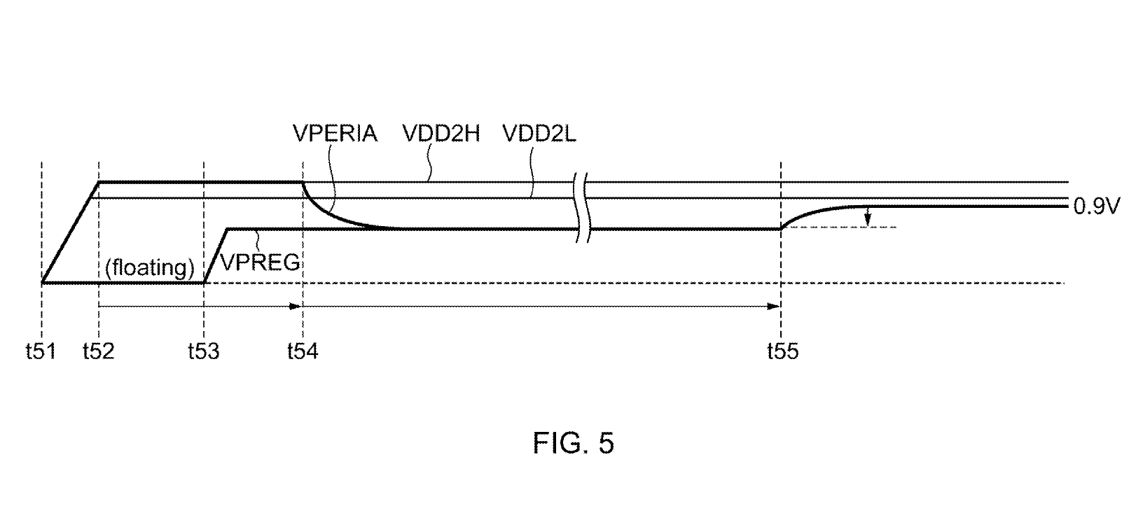

FIG. 5 is a timing chart for explaining changes of the internal power potential VPERIA at the time of turning power on. First, when power is turned on at a time t51, the level of each of the external power potentials VDD2H and VDD2L in the internal voltage generator 120 rises quickly and reaches a predetermined level before a time t52. At the time of turning the power on, the power switch 125 is set to be an ON state by activating the selection signal SEL5. The selection signals SEL1 and SEL2 are both in a deactivated state. Accordingly, the level of the internal power potential VPERIA rises in tandem with the external power potential VDD2H.

Next, at a time t53, the level of the internal power node VN is set to be the regulator potential VPREG by generating the reference potential VPREGref. In a period before the time t53, the internal power node VN is in a floating state. Further, at this time point, by setting the level of the reference potential VPREGref to be lower than the level at the time of normal operation of the semiconductor device, the level of the regulator potential VPREG is set to be lower than the level at the time of normal operation.

Next, at a time t54, the enable signal EN1 is activated after disconnecting the power supply line L4 and the power supply line L1 from each other by deactivating the selection signal SEL5. At this time point, the internal power potential VPERIA is higher than the reference potential VPREGref. Therefore, when the enable signal EN1 is activated, the enable signal EN2 as the output from the comparator 1272 enters a high level and the pull-down transistor 1271 is turned on. Accordingly, the power supply line L4 is discharged and the level of the internal power potential VPERIA is gradually lowered. Thereafter, at a time point where the level of the internal power potential VPERIA reaches the regulator potential VPREG, the enable signal EN2 is changed to a low level and the pull-down transistor 1271 is turned off. Subsequently, the power switch 121 is turned on by activating the selection signal SEL1. Accordingly, the level of the internal power potential VPERIA is clamped to the regulator potential VPREG.

Next, at a time t55, the level of the reference potential VPREGref is set to be the level at the time of normal operation. Accordingly, the level of the regulator potential VPREG also becomes the level at the time of normal operation.

In this manner, the pull-down circuit 127 included in the internal voltage generator 120 functions not only when the level of the internal power potential VPERIA is to be switched but also when power is turned on.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first external power supply line supplied with a first external power voltage;
a second external power supply line supplied with a second external power voltage different from the first external power voltage;
a first internal power supply line;
an internal voltage generator coupled in parallel to the first external power supply line and the second external power supply line and configured to supply a voltage to the first internal power supply line based on a selected one of the first external power voltage and the second external power voltage; and
a pull-down circuit coupled to the first internal power supply line and configured to lower the voltage of the internal power supply line when the voltage of the internal power supply line exceeds a reference voltage.

2. The apparatus of claim 1, wherein the internal voltage generator includes:
a pull-up circuit coupled between the first external power supply line and an internal power node and configured to supply an internal power voltage lower than the first external power voltage to the internal power node;
a first power switch coupled between the internal power node and the first internal power supply line; and
a second power switch coupled between the second external power supply line and the first internal power supply line.

3. The apparatus of claim 1, wherein the first external power voltage is higher than the second external power voltage.

4. The apparatus of claim 3, wherein the pull-down circuit is configured to be deactivated when the voltage of the first internal power supply line is lower than a predetermined voltage.

5. The apparatus of claim 4, wherein the predetermined voltage is lower than the internal power voltage.

6. The apparatus of claim 3, wherein the pull-up circuit includes a pull-up transistor coupled between the first external power supply line and the internal power node, and a first comparator circuit configured to control the pull-up transistor.

7. The apparatus of claim 6, wherein the first comparator circuit has a first input node supplied with the reference voltage, a second input node coupled to the internal power node, and an output node coupled to a control electrode of the pull-up transistor.

8. The apparatus of claim 1, wherein the pull-down circuit includes a pull-down transistor coupled between the first internal power supply line and a third external power supply line, and a second comparator circuit configured to control the pull-down transistor.

9. The apparatus of claim 8, wherein the second comparator circuit has a first input node supplied with the reference voltage, a second input node coupled to the internal power supply line, and an output node coupled to a control electrode of the pull-down transistor.

10. The apparatus of claim 2, further comprising:
a second internal power supply line electrically independent of the first internal power supply line;
a third power switch coupled between the first external power supply line and the second internal power supply line; and
a fourth power switch coupled between the second external power supply line and the second internal power supply line.

11. The apparatus of claim 1, further comprising
a memory cell array;
a row address decoder circuit configured to perform a row access to the memory cell array; and
a column address decoder circuit configured to perform a column access to the memory cell array,
wherein the row address decoder circuit is configured to operate on a voltage supplied from the second internal power supply line, and
wherein the column address decoder circuit is configured to operate on a voltage supplied from the first internal power supply line.

12. The apparatus of claim 2, further comprising a fifth power switch coupled between the first external power supply line and the first internal power supply line.

13. The apparatus of claim 12, wherein the fifth power switch is configured to be temporarily activated after a supply of the first external power voltage to the first external power supply line is started.

14. The apparatus of claim 13, wherein the pull-down circuit is configured to be activated after the fifth power switch is deactivated.

15. An apparatus comprising:
a first external power supply line supplied with a first external power voltage;
a second external power supply line supplied with a second external power voltage lower than the first external power voltage;
a third external power supply line supplied with a third external power voltage lower than the second external power voltage;
an internal power supply line;
a first power switch coupled between the first external power supply line and the first internal power supply line;
a second power switch coupled between the second external power supply line and the first internal power supply line; and
a pull-down circuit coupled between the internal power supply line and the third external power supply line,
wherein the first power switch is configured to be changed from an OFF state to an ON state after the second power switch is changed from an ON state to an OFF state, and
wherein the pull-down circuit is configured to be activated for a part of a time period after the second power switch is changed to an OFF state and before the first power switch is changed to an ON state.

16. The apparatus of claim 15, further comprising a pull-up circuit coupled between the first external power supply line and the first power switch.

17. The apparatus of claim 16,
wherein the pull-up circuit includes a pull-up transistor coupled between the first external power supply line and the first power switch, and a first comparator circuit configured to control the pull-up transistor, and
wherein the first comparator circuit has a first input node supplied with a reference voltage, a second input node coupled to a drain of the pull-up transistor, and an output node coupled to a control electrode of the pull-up transistor.

18. The apparatus of claim 17,
wherein the pull-down circuit includes a pull-down transistor coupled between the internal power supply line and the third external power supply line, and a second comparator circuit configured to control the pull-down transistor, and
wherein the second comparator circuit has a first input node supplied with the reference voltage, a second input node coupled to the internal power supply line, and an output node coupled to a control electrode of the pull-down transistor.

19. An apparatus comprising:
a first power supply line supplied with a first power voltage;
a second power supply line supplied with a second power voltage different from the first power voltage;
first, second, and third transistors coupled in series between the first power supply line and the second power supply line;
a first comparator circuit configured to control the first transistor;
a second comparator circuit configured to control the third transistor; and
a load circuit configured to operate on a voltage appearing at a source of the second transistor,
wherein the first transistor has a first conductivity type,
wherein the second and third transistors have a second conductivity type opposite to the first conductivity type,
wherein the second transistor is configured to be controlled by a control signal,
wherein the first comparator circuit has a first input node supplied with a reference voltage, a second input node coupled to a drain of the first transistor, and an output node coupled to a control electrode of the first transistor,
wherein the second comparator circuit has a first input node supplied with the reference voltage, a second input node coupled to the source of the second transistor, and an output node coupled to a control electrode of the third transistor such that the second comparator circuit is configured to bring the third transistor into an ON state when the voltage appearing at the source of the second transistor is higher than the reference voltage, and
wherein the second comparator circuit is configured to be activated before the control signal is activated.

20. The apparatus of claim 19, wherein the control signal is activated after the second comparator circuit is deactivated.
